(19) United States
(12) Patent Application Publication
(10) Pub. No.: US 2019/0259874 A1
(43) Pub. Date: Aug. 22, 2019

(54) WAFER BASED BEOL PROCESS FOR CHIP EMBEDDING

(71) Applicant: Infineon Technologies AG, Neubiberg (DE)

(72) Inventors: Paul Ganitzer, Finkenstein (AT); Arno Zechmann, Villach (AT); Michael Jacob, Villach (AT)

(21) Appl. No.: 16/398,277

(22) Filed: Apr. 30, 2019

Related U.S. Application Data
(63) Continuation of application No. 14/171,839, filed on Feb. 4, 2014, now abandoned.

(51) Int. Cl. H01L 29/78; H01L 23/31; H01L 29/10; H01L 29/417; H01L 29/45; H01L 29/66; H01L 23/485; H01L 21/283

(52) U.S. Cl. CPC H01L 29/7813; H01L 23/3171; H01L 29/1095; H01L 29/41741; H01L 29/45; H01L 23/53238; H01L 23/485; H01L 21/283; H01L 29/66734; H01L 23/3157; H01L 29/66666; H01L 29/66712

(57) ABSTRACT

In various embodiments a semiconductor device is provided, including a semiconductor body including a drift region and a gate electrode arranged adjacent to the drift region; and a contact structure provided over the drift region of the semiconductor body and having a first metal layer, an adhesion layer over the first metal layer and a second metal layer over the adhesion layer.

### RELATED APPLICATION(S)

This application is continuation of U.S. patent application Ser. No. 14/171,839, filed Feb. 4, 2014, entitled “WAFER BASED BEOL PROCESS FOR CHIP EMBEDDING”, the contents of which are hereby incorporated by reference in their entirety.

### TECHNICAL FIELD

Various embodiments relate to a wafer based BEOL (back end of line) process for chip embedding.

### BACKGROUND

Packaging is the final stage of semiconductor device fabrication, in which the small block of processed semiconductor, i.e. the chip, is placed in a supporting case that prevents physical damage and corrosion. The case, which is commonly referred to as “package”, supports the electrical contacts which connect the chip to a circuit board.

A standard packaging process is usually based on bonding and molding. Interconnects are realized by a galvanic processes and the die is protected with a laminate.

In a new packaging concept, also referred to as Blade package, a chip is attached onto a circuit board. Both the front side and the back side of the chip are electrically contacted with the leadframe via a metal layer. The Blade package is a vertical transistor package optimized for high current handling and easy circuit board layout. Using this technology makes it possible to realize products with lowest on state resistances and highest power density without compromises in performance and cooling.

However, it has been found that common chip concepts, for example relying on SFETx (x standing for 3, 4 or 5) technology, also referred to as “double poly” (i.e. designs with two electrodes insulated from one another in a trench) or its brand name Optimos, are not suitable for the Blade package due to the nature of the metallisation and/or passivation process and therefore, a solution to that problem would be desirable.

### SUMMARY

In various embodiments a semiconductor device is provided, including a semiconductor body including a drift region and a gate electrode arranged adjacent to the drift region; and a contact structure provided over the drift region of the semiconductor body and having a first metal layer, an adhesion layer over the first metal layer and a second metal layer over the adhesion layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of a vertical structure of a field effect transistor manufactured in accordance with a standard process;

FIG. 1B shows a top view of the vertical field effect transistor shown in FIG. 1B;

FIG. 2 shows a vertical structure of a field effect transistor according to various embodiments;

FIG. 3 shows a semiconductor device according to various embodiments;

FIG. 4 shows a further semiconductor device according to various embodiments; and

FIGS. 5 and 6 show methods for manufacturing a semiconductor device according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The Blade package may be understood as an application of the printed circuit board (PCB) in the semiconductor manufacturing technology. In the packaging process, a die may be attached to a leadframe by soldering, such that the back side of the die may be electrically contactable. The front side of the die may be also electrically contacted by a metal layer.

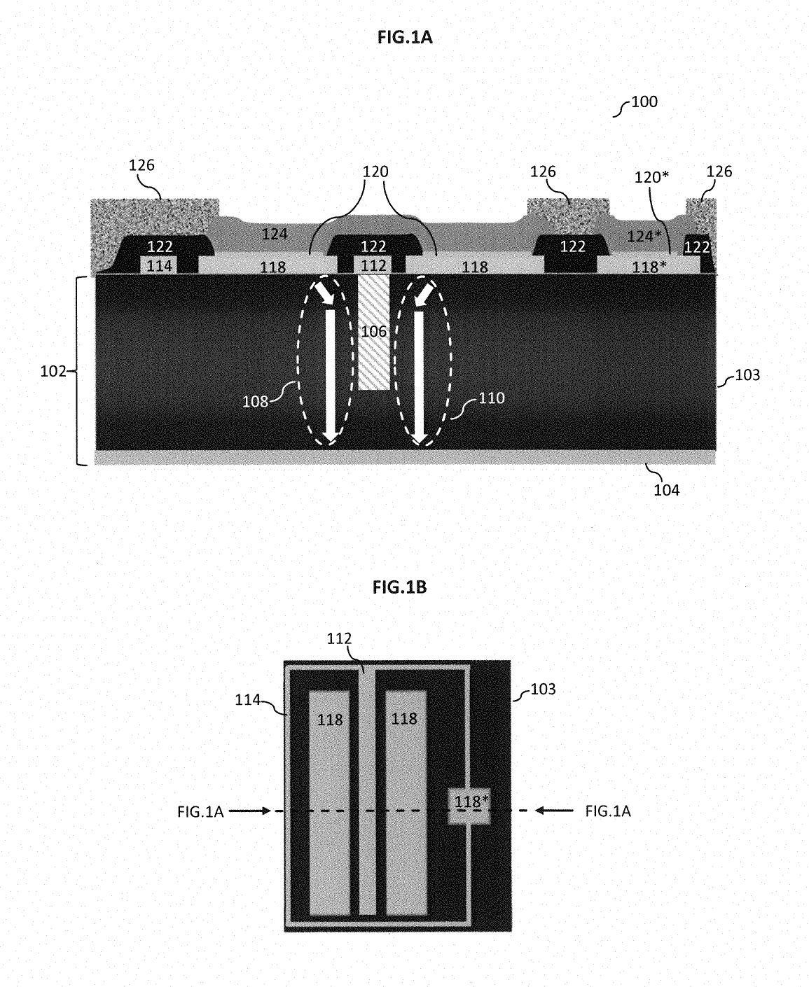

FIG. 1 shows a vertical structure of a field effect transistor 100. The vertical field effect transistor 100 may be manufactured in accordance with the SFET5 technology standard which is a trench technology for power transistors.

The transistor 100 includes a semiconductor body 102 which includes a semiconducting material 103, for example a layer of the semiconductor material 103, and a back side metal layer 104. The back side metal layer 104 is provided on the bottom surface of the layer of semiconductor material 103 and may be used as a thermally optimized die attach by means of diffusion soldering or eutectic bonding. The semiconductor material 103 may be a part of a die incorporating a functional circuit. Differently doped wells may be created within the layer of semiconductor material 103 by means of doping. In this case, a gate electrode 106 is provided in the layer of semiconductor material 103. A first drift region 108 and a second drift region 110 are provided in the layer of semiconductor material 103 adjacent to the gate electrode 106. A layer of dielectric material isolating the gate electrode 106 from the surrounding semiconductor material 103, e.g. from the drift regions 108, 110, is not shown in FIG. 1A. The manufacture of the semiconductor body 102 is performed during the so-called FEOL (front end of line) process. The explicit design of the semiconductor body 102 as schematically shown in FIG. 1A, e.g. the geometrical shape of the doped regions within the layer of semiconductor material 103 is only an exemplary one and may be of course adapted to the specific circuitry which is to be manufactured.

Over the upper surface of the semiconductor body 102 a gate portion 112 is provided which may be electrically coupled to the gate electrode 106. The gate portion 112 is covered by a layer of dielectric material 122, a so-called inter layer dielectric (ILD). The dielectric material may include silicon oxide or silicon nitride. A first metal layer 118 is disposed over the upper surface of the semiconductor body 102 on both sides of the gate portion 112. The first metal layer 118 is subdivided in two or in general more portions thereof, for example a left portion and a right portion referring to the relative locations of the respective portions of the first metal layer 118 on the semiconductor body 102, which are separated from one another by the gate portion 112 and are further isolated from the gate portion 112 by the dielectric material 122. A further gate portion 114 is provided on the upper surface of the semiconductor body 102 adjacent to the left portion of the first metal layer 118 and isolated therefrom by the dielectric material 122 which covers or surrounds the further gate portion 114 in the same way as the gate portion 112 is surrounded by the dielectric material 122. A further first metal layer 118* is provided on the upper surface of the semiconductor body 102 adjacent to the right portion of the first metal layer 118. The further first metal layer 118* is separated from the right portion of the first metal layer 118 by a block of dielectric material 122.

A second metal layer 124, 124* is provided on top of every first metal layer 118, 118*. The second metal layer 124, 124* may include copper. The left portion of the second metal layer 124 over the left and right portion of the first metal layer 118 is a continuous second metal layer 124, i.e. the left portion and the right portion of the first metal layer 118 are electrically coupled to one another by means of the second metal layer 124. The other, right portion of the second metal layer 124* on top of the further first metal layer 118* is electrically isolated from the continuous second metal layer 124 by means of a passivation material 126 provided in a gap separating the left portion of the second metal layer 124 form the right portion of the second metal layer 124*. The passivation material is further provided over the leftmost layer of dielectric material 122 and also on the right side of the right portion of the second metal layer 124*. Due to the nature of the manufacturing process of the field effect transistor 100 involving heating, an intermetallic phase 120, 120* is present at every interface between the first metal layer 118, 118* and the second metal layer 124, 124*.

The left portion and the right portion of the first metal layer 118 and the further portion of the first metal layer 118* may be formed in the same manufacturing process. In fact, a continuous first metal layer, for example including aluminium, may be provided over the top surface of the semiconductor body 102 and subsequently the continuous first metal layer may be structured appropriately (e.g. by an appropriate masking process followed by an etching process) to yield the pattern of first metal portions shown in FIG. 1A. The left portion and the right portion of the first metal layer 118 may be source contacts of the vertical field effect transistor 100. The further portion of the first metal layer 118* may be a gate contact or gate pad of the vertical field effect transistor 100. The gate contact is electrically coupled to the gate portion 112 and to the further gate portion 114. This, however, is not shown in FIG. 1A which is a cross-sectional view of the vertical field effect transistor 100.

FIG. 1B shows a corresponding top view of the vertical field effect transistor 100 from FIG. 1A. The top view shows the stage of the manufacturing process after the source contacts (i.e. the two portions of first metal layers 118 having a rectangular shape in FIG. 1B), the gate contact 118*, the gate portion 112 and the further gate portion 114 have been provided on the top surface of the semiconductor material 102. The gate portion 112 (not shown in FIG. 1A) may be a so-called gate finger which provides an electrical connection between the main gate contact 118* and the gate electrode 106 (not shown in FIG. 1B) buried within the semiconductor material 103. The further gate portion 114 (not shown in FIG. 1B) may be a so-called gate runner which may be seen as a frame structure surrounding the source contacts and providing an electrical connection between the gate contact 118* and the gate portion 112. Furthermore, the further gate portion 114 may have a positive effect on the build-up of a homogenous electric field controlling the switching of the device. It is to be noted that the dimensions of the elements shown in FIG. 1B, in particular their widths and lengths, may differ from their dimensions expected from FIG. 1A. FIG. 1B merely serves a better schematical understanding of the vertical field effect transistor 100 and should not be perceived as limiting in that sense. Furthermore, the design of the gate portion 112 in combination with the further gate portion 114 and the gate contact 118* is only one example of very many possible ways to implement that structure.

Returning back to the cross-sectional view presented in FIG. 1A, it may be seen that the first drift region 108 and the second drift region 110 are both provided underneath the source contacts, i.e. underneath the left portion and right portion of the first metal layer 118. The white arrows within the drift regions 108, 110 indicate the path of charge carriers once an appropriate electric field has been applied to the gate contact 118*. In analogy to the above description, the left portion of the second metal layer 124 and the right portion of the second metal layer 124*, which may include copper, may be formed in the same process step, wherein a uniform second metal layer, for example including copper, may be provided over the semiconductor body 102 with the first metal layer 118, 118* and the dielectric layer 112 being already structured. Subsequently, the uniform second metal layer may be structured according to need to arrive at the pattern including the two portions of the second metal layer 124, 124* as shown in FIG. 1A. In particular, the left portion of the second metal layer 124 arranged over the left portion and the right portion of the first metal layer 118, i.e. the portion of the second metal layer 124 provided over the two source contacts, is electrically isolated from the portion of the second metal layer 124* over the gate contact 118*. In addition, the passivation material 126 is provided at least in the gap between the left portion of the second metal layer 124 and the right portion of the second metal layer 124*.

In the scope of this specification, the reference numbers of layers falling into the scope of the gate contact carry a suffix in the form of asterisk (*), whereas corresponding layers falling into the scope of the source contacts carry the same reference numbers without the asterisk.

The thickness of the layer including the semiconductor material 103 in standard manufacturing processes is approximately in the range of approximately 40 μm to approximately 60 μm. The layers provided on the surface of the semiconductor body 102 add at least approximately further 20 μm, such that the thickness of the whole structure of the vertical field effect transistor 100 shown in FIG. 1A (the thickness being measured from the bottom surface of the back side metal layer 104 to the upper surface of the passivation layer 126) may lie in the range of approximately 60 μm to approximately 70 μm or more.

The design of the vertical field effect transistor 100 shown in FIG. 1A manufactured in accordance with the Optimos technology may be improved in several aspects such that its migration into the Blade package described at the outset is less error-prone. In the following, several issues inherent in the design shown in FIG. 1A will be discussed.

One undesirable aspect of the vertical transistor 100 design is the formation of the intermetallic phase 120, 120* at the interfaces between the several portions of the first metal layer 118, 118* and the portions of the second metal layer 124, 124*. The formation of the intermetallic phase 120, 120* is caused by high temperature process steps during the manufacture of the vertical field effect transistor 100. The intermetallic phase 120, 120* is unwanted in the Blade assembly process and is seen as a flawed region since it is mechanically unstable and thus prone to cause delamination within the device. It is further susceptible to increased etching with respect to other materials such that is reduce the process reliability during the assembly of the device.

A second problematic aspect to be mentioned relates to the second metallic layer 124, 124*. Since structuring of copper layers is rather difficult, the standard thickness of the second metal layer 124, 124* leads to an insufficient thickness after roughening of the copper layer. During provision of vias through a uniform layer of the passivation material 126 by means of a laser, for example, that thin layer may suffer from melting open, down to materials located beneath, for example down to the intermetallic phase 120, 120* or even down to the level of the first metal layer 118, 118* which then becomes exposed, rendering the electrical behaviour of the corresponding electrical contact less or oven predictable.

Furthermore, as shown in FIG. 1A, the left portion of the second metal layer 124 is a continuous layer or a plate which extends from a region above the left portion of the first metal layer 118 to the region above the right portion of the first metal layer 118, thereby covering and being in contact with the dielectric layer 122 which is disposed over the gate portion 112. The continuous layer of second metal layer 124 (i.e. the left portion of the second metal layer 124) helps in establishing a uniform electrical potential thereon and on the two portions of the first metal layer 118 corresponding to source contacts. The electrical contact between the continuous layer of the second metal layer 124 and the leadframe is mostly established by bonding or soldering. However, the presence of the second metal layer 124 above the dielectric layer 122 as well as the interfacial contact between those two layers is problematic. The second metal layer 124 material, that usually being copper, has a relatively high coefficient of thermal expansion in contrast to the relatively low coefficient of thermal expansion of the underlying dielectric material 122. Hence, during the frequent and common temperature changes in the manufacturing process, the second metal layer 124 may exert a shearing force upon the dielectric layer 122 located underneath. This may result in cracks in the dielectric material 122, and, as a worst case scenario, may lead to leakage currents between the left portion of the second metal layer 124 representing the source contact plate and the gate portion 112 being an integral part of the gate structure.

Last but not least, the conventional passivation procedure may prove problematic, as the openings in the passivation material 126 exposing the second metal layer 124, 124*, as mentioned above, may lead to the already too thin second metal layer 124, 124* (usually copper) to be exposed to the roughing procedure performed on the device during its manufacture.

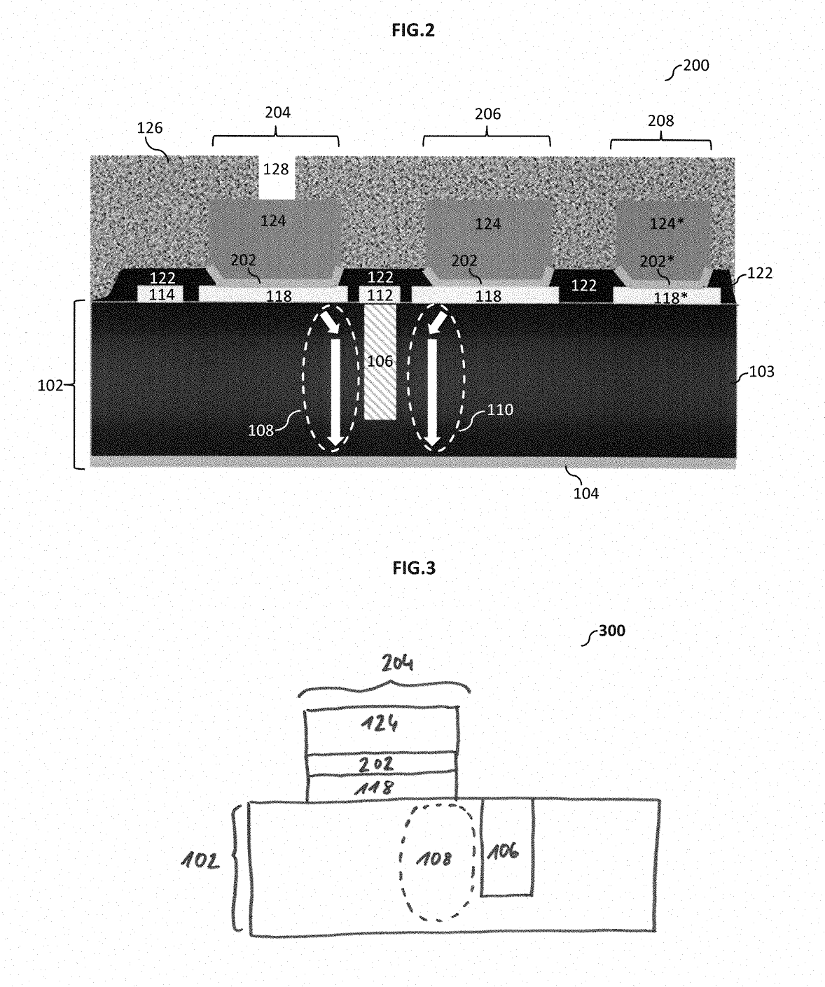

In view of the above problems, the design of the vertical field effect transistor 100 shown in FIG. 1A may be favourably changed as will be explained based on the semiconductor device 200 shown in FIG. 2.

FIG. 2 shows a cross-sectional view of the semiconductor device 200 according to various embodiments. The position of the cross-section within the device corresponds to that of FIG. 1A, as indicated in FIG. 1B. As the semiconductor device 200 according to various embodiments which in this case is configured as a vertical field effect transistor is similar to the vertical field effect transistor 100, the same components/elements will be labelled with the same reference numbers and they will not be described again. Emphasis will be placed on specifically altered aspects which may enable successful integration of the corresponding semiconductor chip into the Blade package.

The semiconductor device 200 includes the semiconductor body 103 having the semiconductor material 103 (e.g. a layer 103 of semiconductor material) and the back side metal layer 104 provided on the bottom side of the semiconductor material 103. The doped structures within the semiconductor material 103 may correspond to the ones described with respect to FIG. 1A, i.e. at least one gate electrode 106 and at least one drift region, e.g. two drift regions 108, 110 may be provided therein by means of doping. A first metal layer 118 including a left portion of the first metal layer 118 and a right portion of the first metal layer 118, each provided on either side of the gate portion 112 and separated therefrom by the dielectric material 122 is also provided on the top surface of the semiconductor body 102, as already described with respect to FIG. 1A. Furthermore, the further gate portion 113 covered by dielectric material 122 and a further portion of the first metal layer 118* are also provided.

The semiconductor device 200 according to various embodiments shown in FIG. 2, in contrast to the device structure shown in FIG. 1A has a different contact structure. Each of the contacts includes a stack of layers and it may be seen that there is no interconnection between the individual contacts at the level of the second metal layer 124, 124* as was the case in the device of FIG. 1A. In detail, the semiconductor device 200 includes a first contact structure 204, a second contact structure 206 and a third contact structure 208. The first contact structure 204 is arranged on the semiconductor body 102 over the first drift region 108. The second contact structure 206 is arranged on the semiconductor body 102 over the second drift region 110 next to the first contact structure 204, spaced apart therefrom and electrically isolated therefrom by a block of dielectric material 122 which covers the gate portion 122 and by a portion of passivation material 126. The third contact structure 208 is arranged on the semiconductor body 102 next to the second contact structure 124, spaced apart therefrom by the dielectric material 122 and a portion of passivation material 126.

The first contact structure 204 may correspond to a first source contact, the second contact structure 206 may correspond to a second source contact and the third contact structure 208 may correspond to a gate contact structure. The reference numbers of layers belonging to the gate contact structure are additionally marked with an asterisk, even though structurally they may be similar or substantially equal to the other contact structures. As the contact structures may be structurally similar, only the first contact structure 204 will be described in detail. Even though the contact structures may be substantially similar, they may differ in their dimensions or specific materials used such that different materials may be used for a given layer as long as they satisfy certain requirements such as conductivity or availability of etching agents, just to name two examples.

The first contact structure may include the first metal layer 118, an adhesion layer 202 arranged over the first metal layer 118 and a second metal layer 124 arranged over the adhesion layer 202. The first metal 118 layer may include aluminium (Al) or an aluminium copper alloy, wherein the content of copper may amount to approximately 0.5%. The andesion layer 202 may include titanium (Ti), tantalum (Ta), titanium tungsten (TiW) or other refractive metals. The second metal layer 124 may include copper (Cu).

As already mentioned, the contact structures 204, 206, 208 are electrically separated from one another by a layer of dielectric material 122 and portions of the passivation material 126 provided on the layers of dielectric material 122. Furthermore, the passivation material 126 may encapsulate the contact structures such that they are not exposed to the exterior. However, openings in the passivation material may be provided to expose the second metal layer 124, 124* for electrical contacting, of which one opening 128 is shown in FIG. 2. Once corresponding openings have been provided over the further contact structures, for example by means of a laser or by an etchant, a RDL (redistribution layer) may be used to interconnect the first contact structure 204 with the second contact structure 206 and further to provide electrical connections between the contact structures 204, 206, 208 and the leadframe (not shown in FIG. 2) to which the semiconductor device 200 according to various embodiments may be attached.

In the following, the differences between the field effect transistor design presented in FIG. 1A and the one presented in FIG. 1B will be discussed.

The adhesion layer 202, 202* provided between the first metal layer 118, 118* and the second metal layer 124, 124* may offer several effects. On the one hand, the adhesion layer 202, 202* may improve the adhesion between the first metal layer 118, 118* and the second metal layer 124, 124*. It has been observed that the mechanical stress within the Blade package is increased in comparison to other standard packages, for example the Sx08 package. The Sx08 package may refer to a standard SMD (surface-mounted device) leadless mold package with a leadframe to which a chip is soldered to. The Sx08 package may be further characterized by a wire bonded or clip soldered gate contact and an ordinary clip soldered source interconnect. Despite providing an optimal boundary surface between the first metal layer 118, 118* and the second metal layer 124, 124*, for example between Al and Cu, via the corresponding intermetallic phases with a thickness of approximately 700 nm, delamination still occurred in typical stress tests. By providing the adhesion layer 202, 202* including an Al and Cu separating material such as Ti, Ta or TiW, a better adhesion between the surface of the first metal layer 118, 118* and the surface of the second metal layer 124, 124* may be achieved and delamination at that interface may be avoided. On the other hand, the adhesion layer 202, 202* may increase the range of available manufacturing temperatures during manufacturing processes such as providing the passivation layer, laser-drilling of vias for metallic interconnects. For example, depositing an imide based passivation is hardly possible without formation of intermetallic phases if the adhesion layer 202, 202* is not in place. The temperature required for imide passivation curing leads to a very strong intermetallic phase formation which, in effect, renders the corresponding electrical contact inoperable. In that sense, the adhesion layer 202, 202* may be seen as a layer preventing a reaction between the first metal layer 118, 118* and the second metal layer 124, 124*, for example during the imide passivation curing and may therefore be a reaction preventing and adhesion layer 202. Furthermore, the adhesion layer 202, 202* may increase the process reliability, since it provides a solid stoppage layer during the process of providing openings 128 in the passivation material 126 by a laser. In other words, the adhesion layer 202, 202* may prevent a faulty drilling of the via hole (opening 128) beyond the adhesion layer 202, 202*. With regard to this aspect, the non-existence of the intermetallic phase 120, 120* (see FIG. 1A) may be also seen as beneficial, since the interface between the different intermetallic phases is mechanically unstable. In case of an unintentional drilling through the second metal layer 124, 124* while the openings 128 in the passivation material 126 are provided, the intermetallic phase 120, 120* may be removed thereby exposing the first metal layer 118, 118* to succeeding wet processes in which the first metal layer 118, 118* may be removed or partially etched, such that the surface of the semiconductor material 103 may be exposed. That chain of events may in effect render the contact electrically inferior.

The thickness of the second metal layer 124, 124* is increased with respect to standard designs and may lie in the region of 5 μm or more and may amount to 6 μm, 7 μm, 9 μm, 10 μm or more, for example. The increased thickness of the second metal layer 124, 124* allows for a secure roughening thereof which takes place at a later time during the manufacturing process. A thickness of the second metal layer 124, 124* below 5 μm may be critical in that respect as during the roughening process it may be completely removed at some spots. The provision of a thicker second metal layer 124, 124* may further increase the thermal capacity and the stability with regard to electromigration. Those aspects become, determined by the system, particularly relevant at the circumferential edge of the interface between the opening 128 (or via) and the second metal layer 124, 124*. During operation, a steady current flow approximately 3.5 A may be carried by the via which may have a diameter of approximately 50 μm. However, the current density within the bulk of the material filling the via, e.g. copper, is practically zero as the current predominantly flows at the edge of the block of material filling the via, e.g. The transition from the via to the second metal layer 124, 124* may be particularly critical at the circumferential edge of the via in common designs having a thin layer of the second metal layer 124, 124* as the thin metal layer 124, 124* may need to handle very high current densities. Here, the provision of a thicker second metal layer 124, 124* in accordance with various embodiments may be beneficial. A thicker second metal layer 124, 124* translating into a higher conductivity, may enable a wider field of design possibilities and may remove the necessity to electrically connect each source contact at a dense contact spacing by a via to achieve a homogenous current distribution. Furthermore, the provision of a thicker second metal layer 124, 124* may increase the robustness of the corresponding field effect transistor in avalanche mode. In case of copper as the material comprised by the second metal layer 124, 124*, common deposition procedures such as PVD (physical vapour deposition) or ECD (electrochemical deposition) may be used.

As shown in FIG. 2, the second metal layer 124, 124* covers the first metal layer 118, 118* in each region of a contact structure or, in other words, it is deposited over the first metal layer 118, 118*, for example aluminium, such that no portion of the first metal layer 118, 118* remains exposed which may improve processability. In comparison to the standard design of a vertical field effect transistor 100 shown in FIG. 1A, the provision of separate, discrete contact structures 204, 206, 208 may be advantageous in the sense that there is no second metal layer 124, 124* provided on the dielectric material 122 covering the gate portion 112. The gate portion 112 which may include (or be processed from) the first metal layer 118, 118* is not covered by the second metal layer 124, 124* but is only covered by the passivation material 126. This may prevent the formation of cracks in the dielectric material 122 and leakage currents between the second metal layer 124 and the gate portion 112 as there is no drastic difference between the coefficient of thermal expansion of the dielectric layer 122 and the coefficient of thermal expansion of the passivation material 126.

The semiconductor device 200 according to various embodiments may further include a tungsten layer (not shown in FIG. 2) arranged between the first metal layer 118, 118* and the surface of the semiconductor material 103. During manufacture of the semiconductor device 200 the tungsten layer may undergo a fine pitch structuring process in order to provide connections for connecting small current and/or temperature sensors which may be sensing structures, for example, embedded in the drift region provided within the semiconductor material 103. The current sensor may be based on a reference cell which has a known surface area. By measuring the current flow though that reference cell, the current flow though the contact structure may be derived. The temperature sensor may be, for example, based on a polysilicon resistor which has a temperature dependent resistance and may be placed within the semiconductor device 200 according to various embodiments. The fine pitch structured tungsten layer may provide fine connection structures (e.g. wires) for connecting the sensors with corresponding controllers.

The layer of passivation material 126 may include various organic materials such as imide or epoxy. After the passivation material 126 has been deposited on the semiconductor device 200 according to various embodiments, the openings 128 may be provided in the passivation material 126 for contacting the second metal layer 124, 124*, for example by a laser. However, the passivation layer 126 may remain unperforated or “unopened” (i.e. without openings 128 being provided therein) and the openings 128 may be provided therein, for example by drilling with a laser, when the wafer is being diced by means of a saw frame. This allows more flexibility with respect to the used package technology (such as die attach, roughening of the second metal layer) and may lead to a more stable mechanical connection between the chip and the package.

A further difference between the standard vertical field effect transistor 100 shown in FIG. 1A and the semiconductor device 200 according to various embodiments may be seen in the usage of a thin wafer technology. As mentioned previously, the whole workpiece as shown in FIG. 1A may have a thickness in the range of approximately 60 μm to approximately 100 μm. The thickness of the layer of the semiconductor material 103 may lie in the range of approximately 40 μm to approximately 80 μm such that a thickness of the whole semiconductor device 200 according to various embodiments, measured from the bottom surface of the back metal layer 103 to the upper surface of the layer including the passivation material 126, may lie in the range of approximately 70 μm or less. This allows for a more efficient manufacturing of the wiring structure, for example the RDL, for electrical contacting of the contact structures 204, 206, 208 and of the back side metal layer which may be configured as a drain contact of the device. The openings 128 (or vias) in the passivation material 126 to the source contact structures 204, 206 and the openings (or vias) in the surrounding passivation material 126 to the drain contact may have the same geometrical shapes. Due to the relatively small thickness of the layer containing the semiconductor material 103, they may be simultaneously filled galvanically with the metallic material forming the wiring structure. By employing thin substrates leading to thin chips with a thickness of 70 μm or less, the overall topography may be held very compact. Due to the relatively small offset between the surface of the leadframe (not shown in FIG. 2A) on which the semiconductor device 200 may be mounted and the surface of the semiconductor device 200 (corresponding to the upper surface of the layer containing the passivation material 126) of approximately 70 μm or less, the laminating process of the semiconductor device 200 to the leadframe may be performed without a pre-structured laminate material without stabilizing fillers which would be necessary if the described offset was larger.

The electrical and thermal coupling of the semiconductor device 200 according to various embodiments to the leadframe may be achieved by a thin metallic soldering connection. The soldering connection as such may be performed by means of diffusion soldering or eutectic soldering. The materials used for that process may include metal compounds on the basis of gold (Au), tin (Sn) and/or copper (Cu).

The aspects described above are based on structural features which have been also explained on the basis of FIG. 2. Each structural feature may have a number of favourable effects on a corresponding semiconductor device. It goes without saying that not all aspects need to be realized in a semiconductor device. The described aspects may rather be seen as a catalogue of individual features having certain advantages if implemented, and the person skilled in the art may implement an arbitrary combination of those to solve problems he or she is faced with. However, it may well be that implementing a larger number of the described features into a semiconductor device may have a synergetic effect. The described aspects may prove helpful in modifying standard manufacturing processes to produce semiconductor devices which may be successfully used with the Blade packaging technology. In the following, reference numbers already used while discussing the vertical field effect transistor 100 shown in FIG. 1A and the semiconductor device 200 according to various embodiments shown in FIG. 2 will be used.

In FIG. 3, a semiconductor device 300 according to various embodiments is shown. The semiconductor device 300 may include a semiconductor body 102 having a drift region 108 and a gate electrode 106 arranged adjacent to the drift region 108; and a contact structure 204 provided over the drift region 108 of the semiconductor body 102 and having a first metal layer 118, an adhesion layer 202 over the first metal layer 118 and a second metal layer 124 over the adhesion layer 202. The semiconductor device 300 according to various embodiments may be further complemented by any number of beneficial features described above with reference to the semiconductor device 200 shown in FIG. 2A.

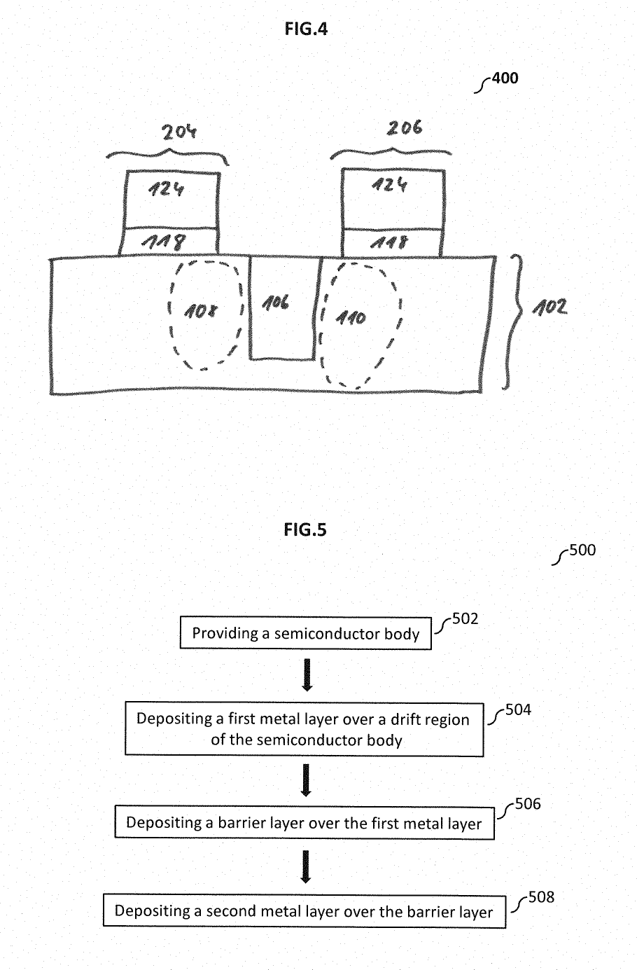

FIG. 4 shows a semiconductor device 400 according to various further embodiments. The semiconductor device 400 may include a semiconductor body 102 having a first drift region 108, a second drift region 110 and a gate electrode 106 arranged between the drift regions. The semiconductor device 400 according to various embodiments may further have a first contact structure 204 provided over the first drift region 108 of the semiconductor body 102 and having a first metal layer 118 and a second metal layer 124 over the first metal layer 118; a second contact structure 206 provided over the second drift region 110 of the semiconductor body 102 and having a first metal layer 118 and a second metal layer 124 over the first metal layer 118, wherein the second contact structure 206 is laterally separated from the first contact structure 204. The semiconductor device 400 according to various embodiments may be further complemented by any number of beneficial features described above with reference to the semiconductor device 200 shown in FIG. 2A.

FIG. 5 shows a flow diagram 500 which outlines a method for manufacturing a semiconductor device, for example the semiconductor device 400 shown in FIG. 4. In a first step 502, the method may include providing a semiconductor body including a drift region and a gate electrode arranged adjacent to the drift region. In a next step 504, the method may include depositing a first metal layer over the drift region of the semiconductor body. In a next step 506, the method may include depositing an adhesion layer over the first metal layer. In a next step 508 the method may include depositing a second metal layer over the adhesion layer, wherein the stack comprising the first metal layer, the adhesion layer and the second metal layer forms a contact structure. Further process steps may be added in accordance with the physical features of the semiconductor device 200 according to various embodiments described above.

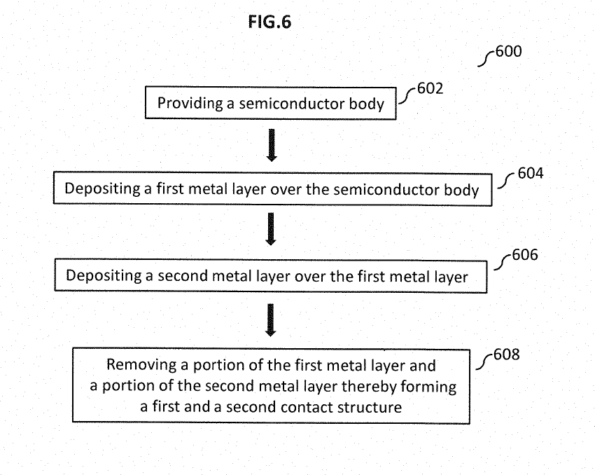

FIG. 6 shows a flow diagram 600 which outlines a further method for manufacturing a semiconductor device, for example the semiconductor device 300 shown in FIG. 3. In a first step 602, the method may include providing a semiconductor body including a first drift region, a second drift region and a gate electrode arranged between the drift regions. In a next step 604, the method may include depositing a first metal layer over the semiconductor body. In a further step 606, the method may include depositing a second metal layer over the first metal layer. In a yet further step 608, the method may include removing a portion of the first metal layer and a portion of the second metal layer in a region between the first drift region and the second drift region thereby forming a first contact structure over the first drift region and a second contact structure over the second drift region, wherein the first contact structure and the second contact structure are laterally separate from one another and each comprise a portion of the second metal layer arranged over a portion of the first metal layer Further process steps may be added in accordance with the physical features of the semiconductor device 200 according to various embodiments described above.

In accordance with various embodiments, a semiconductor device is provided which may include a semiconductor body including a drift region and a gate electrode arranged adjacent to the drift region; and a contact structure provided over the drift region of the semiconductor body and having a first metal layer, an adhesion layer over the first metal layer and a second metal layer over the adhesion layer.

According to various further embodiments, the semiconductor device may further include a further drift region arranged adjacent to the gate electrode such that the gate electrode may be arranged between the two drift regions.

According to various further embodiments the semiconductor device may further include a further contact structure provided over the further drift region of the semiconductor body and having a first metal layer, an adhesion layer over the first metal layer and a second metal layer over the adhesion layer.

According to various further embodiments of the semiconductor device the second contact structure may be laterally separated from the first contact structure.

According to various further embodiments of the semiconductor device the first metal layer of the contact structure and the first metal layer of the further contact structure may include aluminium.

According to various further embodiments of the semiconductor device the adhesion layer of the contact structure and the adhesion layer of the further contact structure may include titanium tungsten.

According to various further embodiments of the semiconductor device the second metal layer of the contact structure and the second metal layer of the further contact structure may include copper.

According to various further embodiments of the semiconductor device the second metal layer may have a thickness of more than 5 micrometers.

According to various further embodiments the semiconductor device may further include a gate portion provided over the gate electrode of the semiconductor body between the contact structures_and electrically coupled to the gate electrode.

According to various further embodiments the semiconductor device may further include a dielectric material provided between the contact structures and covering the gate portion.

According to various further embodiments the semiconductor device may further include passivation material provided over the dielectric material between the contact structures. The passivation material may be also provided over portions of the contact structures.

According to various further embodiments of the semiconductor device the upper surfaces of the second metal layer of the contact structure and of the second metal layer of the further contact structure may be level.

According to various further embodiments of the semiconductor device the passivation material may be provided over the contact structures thereby encapsulating the contact structures.

According to various further embodiments the semiconductor device may further include an opening provided in the passivation material over the upper surface of each of the contact structures exposing the upper surface of each of the contact structures.

According to various further embodiments the semiconductor device may further include a further gate portion provided over the semiconductor body and electrically coupled to the gate portion, the further gate portion being covered by a dielectric material.

According to various further embodiments the semiconductor device may further include a gate contact structure provided over semiconductor body and having a first metal layer, an adhesion layer over the first metal layer and a second metal layer over the adhesion layer, wherein the first metal layer of the gate contact structure may be electrically coupled with the gate portion and the further gate portion.

According to various further embodiments the semiconductor device may further include a tungsten layer arranged between the first metal layer of each of the contact structures and the semiconductor body.

According to various further embodiments of the semiconductor device the tungsten layer may include interconnections to connect a sensor for measuring at least one of temperature and current. The tungsten layer may be a fine pitch structured tungsten layer.

According to various further embodiments, the adhesion layer may be a reaction protection and adhesion layer.

In accordance with various further embodiments, a semiconductor device is provided which may include a semiconductor body including a first drift region, a second drift region and a gate electrode arranged between the drift regions; a first contact structure provided over the first drift region of the semiconductor body and having a first metal layer and a second metal layer over the first metal layer; a second contact structure provided over the second drift region of the semiconductor body and having a first metal layer and a second metal layer over the first metal layer, wherein the second contact structure may be laterally separated from the first contact structure.

According to various further embodiments the semiconductor device may further include an adhesion layer provided between the first metal layer and the second metal layer within each of the contact structures.

According to various further embodiments of the semiconductor device the first metal layer of the first contact structure and the first metal layer of the second contact structure may include aluminium.

According to various further embodiments of the semiconductor device the adhesion layer of the first contact structure and the adhesion layer of the second contact structure may include titanium tungsten.

According to various further embodiments of the semiconductor device the second metal layer of the first contact structure and the second metal layer of the second contact structure may include copper.

According to various further embodiments of the semiconductor device the second metal layer may have a thickness of more than 5 micrometers.

According to various further embodiments the semiconductor device may further include a gate portion provided over the gate electrode of the semiconductor body between the contact structures and electrically coupled to the gate electrode.

According to various further embodiments the semiconductor device may further include dielectric material provided between the contact structures and covering the gate portion.

According to various further embodiments the semiconductor device may further include passivation material provided over the dielectric material between the contact structures. The passivation material may be also provided over portions of the contact structures.

According to various further embodiments of the semiconductor device the upper surfaces of the second metal layer of the first contact structure and of the second metal layer of the second contact structure may be level.

According to various further embodiments of the semiconductor device the passivation material may be provided over the contact structures thereby encapsulating the contact structures.

According to various further embodiments the semiconductor device may further include an opening provided in the passivation material over the upper surface of each of the contact structures exposing the upper surface of each of the contact structures.

According to various further embodiments the semiconductor device may further include a further gate portion provided over the semiconductor body and electrically coupled to the gate portion, the further gate portion being covered by a dielectric material.

According to various further embodiments the semiconductor device may further include a further contact structure provided over semiconductor body and having a first metal layer, an adhesion layer over the first metal layer and a second metal layer over the adhesion layer, wherein the first metal layer of the further contact structure may be electrically coupled with the gate portion and the further gate portion.

According to various further embodiments the semiconductor device may further include a tungsten layer arranged between the first metal layer of each of the contact structures and the semiconductor body.

According to various further embodiments of the semiconductor device the tungsten layer may include interconnections to connect a sensor for measuring at least one of temperature and current. The tungsten layer may be a fine pitch structured tungsten layer.

According to various further embodiments the semiconductor device may further include a backside metal layer provided on the backside of the semiconductor body.

According to various further embodiments of the semiconductor device the semiconductor device may be configured as a vertical transistor.

According to various further embodiments of the semiconductor device the backside metal layer may be configured as a drain terminal.

According to various further embodiments of the semiconductor device the first contact structure and the second contact structure may be configured as source terminals.

In accordance with various embodiments a method for manufacturing a semiconductor device is provided, wherein the method may include providing a semiconductor body including a drift region and a gate electrode arranged adjacent to the drift region; depositing a first metal layer over the drift region of the semiconductor body; depositing an adhesion layer over the first metal layer; and depositing a second metal layer over the adhesion layer, wherein the stack comprising the first metal layer, the adhesion layer and the second metal layer may form a contact structure.

In accordance with various further embodiments a method for manufacturing a semiconductor device is provided, wherein the method may include providing a semiconductor body including a first drift region, a second drift region and a gate electrode arranged between the drift regions; depositing a first metal layer over the semiconductor body; depositing a second metal layer over the first metal layer; removing a portion of the first metal layer and a portion of the second metal layer in a region between the first drift region and the second drift region, such that a first contact structure is formed over the first drift region and a second contact structure is formed over the second drift region, wherein the first contact structure and the second contact structure are laterally separate from one another and each include a portion of the second metal layer arranged over a portion of the first metal layer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

To the extent any amendments, characterizations, or other assertions previously made (in this or in any related patent applications or patents, including any parent (U.S. patent application Ser. No. 14/171,839), sibling, or child with respect to any art, prior or otherwise, could be construed as a disclaimer of any subject matter supported by the present disclosure of this application, Applicant hereby rescinds and retracts such disclaimer. In particular, Applicant rescinds any disclaimer in the parent application, U.S. patent application Ser. No. 14/171,839, that may have resulted from the amendment to the claims of the parent application that lead to the allowance of the claims therein. Applicant respectfully submits that any prior art previously considered in the parent application or any other related patent applications or patents, including any parent, sibling, or child, may need to be re-visited or reconsidered.

What is claimed is:

1. A semiconductor device, comprising:
a semiconductor body having a front side and a back side opposite to the front side, the semiconductor body comprising a semiconductor layer, a first drift region and a first gate electrode arranged laterally adjacent to the first drift region, wherein the first gate electrode vertically extends from the front side of the semiconductor body towards the back side of the semiconductor body, and
a first contact structure provided over the semiconductor body and at least partially horizontally overlapping the first drift region of the semiconductor body, the first contact structure including a first metal layer contacting the semiconductor body at the front side, an adhesion layer disposed over the first metal layer, and a second metal layer disposed over the adhesion layer, wherein the first metal layer of the first contact structure and the first gate electrode do not horizontally overlap.

2. The semiconductor device of claim 1, further comprising:
a second contact structure provided over the semiconductor body and laterally adjacent to the first gate electrode, the second contact structure including a first metal layer contacting the semiconductor body at the front side, an adhesion layer disposed over the first metal layer, and a second metal layer disposed over the adhesion layer, wherein the first metal layer of the second contact structure and the first gate electrode do not horizontally overlap.

3. The semiconductor device of claim 2, further comprising:
a second drift region of the semiconductor body, wherein the first gate electrode is arranged laterally adjacent to the second drift region; and wherein the second contact structure at least partially horizontally overlaps the second drift region of the semiconductor body.

4. The semiconductor device of claim 2, further comprising:
a gate portion disposed at the front side of the semiconductor body, wherein the gate portion is electrically coupled to the first gate electrode and is at least partially disposed between the first and second contact structures.

5. The semiconductor device of claim 2, further comprising:
a third contact structure provided over the semiconductor body, the third contact structure including a first metal layer contacting the semiconductor body at the front side, an adhesion layer disposed over the first metal layer, and a second metal layer disposed over the adhesion layer, wherein the first metal layer of the third contact structure is physically and electrically coupled to gate portion.

6. The semiconductor device of claim 5, wherein top surfaces of the first metal layers of the first, second, and third contact structures are coplanar.

7. The semiconductor device of claim 2, wherein the first metal layers of the first and second contact structures include aluminum.

8. The semiconductor device of claim 2, wherein the adhesion layers of the first and second contact structures include titanium, tantalum, or titanium tungsten.

9. The semiconductor device of claim 2, wherein the second metal layers of the first and second contact structures include copper.

10. The semiconductor device of claim 4, further comprising: dielectric material provided between the first and second contact structures that covers the gate portion.

11. The semiconductor device of claim 10, further comprising: passivation material provided over the dielectric material between the first and second contact structures.

12. The semiconductor device of claim 11, wherein the passivation material is further provided over the first and second contact structures so as to encapsulate the contact structures.

13. The semiconductor device of claim 12, further comprising: an opening provided in the passivation material over the upper surface of each of the first contact structure exposing an upper surface of the first contact structure.

14. The semiconductor device of claim 4, further comprising: a further gate portion provided over the semiconductor body that is electrically coupled to the gate portion, the further gate portion being covered by dielectric material.

15. The semiconductor device of claim 2, wherein the second contact structure is laterally and physically separate from the first contact structure.

16. The semiconductor device of claim 2, wherein upper surfaces of the second metal layer of the first contact structure and of the second metal layer of the second contact structure are level.

17. The semiconductor device of claim 4, wherein upper surfaces of the first metal layer of the first contact structure and of the gate portion are level.

18. The semiconductor device of claim 1, further comprising:
a back side metal layer provided at the back side of the semiconductor body.

19. The semiconductor device of claim 2, wherein a thickness of the second metal layer of the first and second contact structures is the range from 5 μm to 10 μm.

20. The semiconductor device of claim 1, wherein a thickness of the semiconductor device is in the range from 60 μm to 100 μm.
